(19) United States
(12) Patent Application Publication
(10) Pub. No.: US 2017/0125452 A1
(43) Pub. Date: May 4, 2017

(54) SEMICONDUCTOR DEVICE

(71) Applicant: SHARP KABUSHIKI KAISHA, Osaka (JP)

(72) Inventors: Keisuke IDE, Osaka (JP); Takao SAITOH, Osaka (JP); Yohsuke KANZAKI, Osaka (JP); Yutaka TAKAMARU, Osaka (JP); Seiji KANEKO, Osaka (JP); Hiroshi MATSUKIZONO, Osaka (JP); Tadayoshi MIYAMOTO, Osaka (JP)

(73) Assignee: Sharp Kabushiki Kaisha, Osaka (JP)

(21) Appl. No.: 15/318,622

(22) PCT Filed: Jun. 9, 2015
(86) PCT No.: PCT/JP2015/066567

§ 371 Date: Dec. 13, 2016

(30) Foreign Application Priority Data
Jun. 17, 2014 (JP) 2014-124185

(51) Int. Cl. H01L 27/12; H01L 29/24; H01L 29/786; G09G 3/36; G02F 1/1368

(52) U.S. Cl. CPC H01L 27/1251; G09G 3/3648; G02F 1/1368; H01L 27/1225; H01L 29/7869; H01L 29/78696; H01L 29/24; H01L 29/78675; H01L 29/78648; H01L 27/1274; G09G 2330/021; G09G 3/3677; G09G 3/3688

(57) ABSTRACT

A semiconductor device (100) includes a substrate (11), a first TFT (10), and a second TFT (20). The first TFT includes a first semiconductor layer (12) that is supported by the substrate, a first gate electrode (14) that is formed on the first semiconductor layer and overlaps with the first semiconductor layer with a first gate insulating layer (13) interposed therebetween, a first insulating layer (16) that covers the first gate electrode, and a first source electrode (17s) and a first drain electrode (17d) that are formed on the first insulating layer and are connected to the first semiconductor layer. The second TFT includes a second gate electrode (22) that is supported by the substrate, a second semiconductor layer (25) that contains an oxide semiconductor and is formed overlapping with the second gate electrode with a second gate insulating layer (23) interposed therebetween, and a second source electrode (24s) and a second drain electrode (24d) that are formed between the second gate insulating layer and the second semiconductor layer. The first semiconductor layer and the second gate electrode are both formed from a same semiconductor film (52).

### TECHNICAL FIELD

The present invention relates to a semiconductor device that includes a thin film transistor (TFT).

### BACKGROUND ART

In recent years, display devices such as liquid crystal display devices have been used widely in mobile phones, smartphones, tablet-type mobile devices, and the like. Moreover, monolithic driver-type display devices (devices with integrated driver circuits or integrated peripheral circuits) are being developed in order to achieve increased miniaturization and thinner (narrower) frame regions in such display devices. Here, “frame region” refers to a region that does not contribute to displaying images, such as that present around the periphery of the display region. In monolithic driver-type display devices, pixel-driving TFTs and driver circuit TFTs are formed on the same substrate. Here, “pixel-driving TFTs” refers to TFTs that are connected to pixels and “driver circuit TFTs” refers to TFTs included in a driver IC that supplies signals to the pixel-driving TFTs.

There is also demand for increased reductions in power consumption and thinner frames in monolithic driver-type display devices. Using different types of TFTs with mutually different properties for the pixel-driving TFTs and the driver circuit TFTs has been proposed as one way to achieve this. For example, using TFTs that have a high mobility and a low threshold voltage for the driver circuit TFTs makes it possible to operate the driver circuit TFTs at a high speed, thereby making it possible to reduce power consumption and/or make the frame thinner in the display device. Meanwhile, prioritizing use of TFTs with low leakage current for the pixel-driving TFTs makes it possible to drive the display device at a low frequency, thereby making it possible to reduce power consumption in the display device.

Patent Document 1 and Patent Document 2 disclose display devices that include pixel-driving TFTs and driver circuit TFTs on a substrate. Here, TFTs in which an oxide semiconductor is used as the material for the semiconductor layer (active layer) are used for the pixel-driving TFTs, and TFTs in which low-temperature polysilicon (LTPS) is used as the material for the semiconductor layer are used for the driver circuit TFTs.

### RELATED ART DOCUMENTS

### Patent Documents

Patent Document 1: Japanese Patent Application Laid-Open Publication No. 2010-3910

Patent Document 2: WO 2012/176422

### SUMMARY OF THE INVENTION

### Problems to be Solved by the Invention

However, the display device disclosed in Patent Document 1 suffers from the following problem. The pixel-driving TFTs in the display device disclosed in Patent Document 1 are top-contact TFTs in which a source electrode and a drain electrode are formed contacting the upper surface of the oxide semiconductor layer. Typically, when forming top-contact TFTs, an insulating layer is formed contacting at least a channel in the upper surface of the oxide semiconductor layer. This insulating layer functions as an etch stop and protects the channel region from etching when the source electrode and the drain electrode are formed. The etch stop reduces the damage received by the semiconductor layer of the TFT and thereby makes it possible to reduce variation in TFT performance. Therefore, in the display device disclosed in Patent Document 1, forming this insulating layer that functions as an etch stop is problematic in that doing so increases the number of manufacturing steps (number of photomasks).

The present invention aims to reduce power consumption in a semiconductor device that includes TFTs and/or to make it possible to achieve a thinner frame without increasing the number of manufacturing steps.

### Means for Solving the Problems

A semiconductor device according to an embodiment of the present invention includes: a substrate; a first thin film transistor including a first semiconductor layer supported by the substrate, a first gate electrode formed on the first semiconductor layer so as to overlap the first semiconductor layer with a gate insulating layer therebetween, a first insulating layer covering the first gate electrode, and a first source electrode and a first drain electrode formed on the first insulating layer and connected to the first semiconductor layer; and a second thin film transistor including a second gate electrode supported by the substrate, a second semiconductor layer containing an oxide semiconductor and formed so as to overlap the second gate electrode with a second gate insulating layer therebetween, and a second source electrode and a second drain electrode formed between the second gate insulating layer and the second semiconductor layer, wherein the first semiconductor layer and the second gate electrode are formed from a same semiconductor film.

In one embodiment, the first gate insulating layer and the second gate insulating layer are formed from a same first insulating film.

In one embodiment, the first gate electrode, the second source electrode, and the second drain electrode are formed from a same first conductive film.

One embodiment further includes: a second insulating layer covering the second semiconductor layer, wherein the first insulating layer and the second insulating layer are formed from a same second insulating film.

One embodiment further includes a third gate electrode overlapping the second semiconductor layer with the second insulating layer interposed therebetween.

In one embodiment, the first source electrode, the first drain electrode, and the third gate electrode are formed from a same second conductive film.

In one embodiment, the second gate electrode is electrically connected to the third gate electrode.

In one embodiment, the second semiconductor layer contains an In—Ga—Zn—O semiconductor.

In one embodiment, the second semiconductor layer contains an In—Ga—Zn—O semiconductor.

In one embodiment, the In—Ga—Zn—O semiconductor contains a crystalline portion.

One embodiment further includes: a third thin film transistor including a fourth gate electrode supported by the substrate, a third semiconductor layer containing an oxide semiconductor and formed so as to overlap the fourth gate electrode with a third gate insulating layer therebetween, and a third source electrode and a third drain electrode formed between the third gate insulating layer and the third semiconductor layer, wherein the third drain electrode is electrically connected to the first drain electrode.

In one embodiment, the third semiconductor layer contains an In—Ga—Zn—O semiconductor.

In one embodiment, the In—Ga—Zn—O semiconductor of the third semiconductor layer contains a crystalline portion.

### Effects of the Invention

An embodiment of the present invention makes it possible to reduce power consumption in a semiconductor device that includes TFTs and/or to make it possible to achieve a thinner frame without increasing the number of manufacturing steps.

### BRIEF DESCRIPTION OF THE DRAWINGS

FIGS. 1(a) and 1(b) schematically illustrate a semiconductor device 100 according to an embodiment of the present invention. FIG. 1(a) is a cross-sectional view schematically illustrating the semiconductor device 100 along line 1A-1A′ in FIG. 1(b), and FIG. 1(b) is a plan view schematically illustrating the semiconductor device 100.

FIGS. 2(a) and 2(b) schematically illustrate a semiconductor device 110 according to another embodiment of the present invention. FIG. 2(a) includes cross-sectional views schematically illustrating the semiconductor device 110 along line 2Aa-2Aa′ and line 2Ab-2Ab′ in FIG. 2(b), FIG. 2(b) is a plan view schematically illustrating the semiconductor device 110, and FIG. 2(c) is a circuit diagram of a second TFT 20a of the semiconductor device 110.

FIGS. 3(a) and 3(b) schematically illustrate a semiconductor device 120 according to yet another embodiment of the present invention. FIG. 3(a) is a cross-sectional view schematically illustrating the semiconductor device 120 along line 3A-3A′ in FIG. 3(b), FIG. 3(b) is a plan view schematically illustrating the semiconductor device 120, and FIG. 3(c) is a circuit diagram of a second TFT 20b of the semiconductor device 120.

FIGS. 4(a) to 4(c) are cross-sectional views schematically illustrating steps in an example of a method of manufacturing the semiconductor device 110.

FIGS. 5(a) and 5(b) are cross-sectional views schematically illustrating steps in the example of the method of manufacturing the semiconductor device 110.

FIGS. 6(a) and 6(b) schematically illustrate a semiconductor device 130 according to yet another embodiment of the present invention. FIG. 6(a) includes cross-sectional views schematically illustrating the semiconductor device 130 along line 6Aa-6Aa′ and line 6Ab-6Ab′ in FIG. 6(b), and FIG. 6(b) is a plan view schematically illustrating the semiconductor device 130.

FIGS. 7(a) and 7(b) schematically illustrate a semiconductor device 140 according to yet another embodiment of the present invention. FIG. 7(a) includes cross-sectional views schematically illustrating the semiconductor device 140 along line 7Aa-7Aa′ and line 7Ab-7Ab′ in FIG. 7(b), and FIG. 7(b) is a plan view schematically illustrating the semiconductor device 140.

### DETAILED DESCRIPTION OF EMBODIMENTS

Next, semiconductor devices according to embodiments of the present invention will be described with reference to figures. The semiconductor devices according to these embodiments are display devices (such as liquid crystal display devices or organic electroluminescent (EL) display devices, for example) or TFT substrates for use in a display device, for example. In the examples described below, it is assumed that the semiconductor devices are display devices (and more specifically, liquid crystal display devices). Note, however, that the semiconductor devices according to these embodiments of the present invention are not limited to being display devices. Moreover, the present invention is not limited to the examples of the embodiments described below. In the figures described below, the same reference characters are used for components that have substantially the same function, and redundant descriptions of such components will sometimes be omitted.

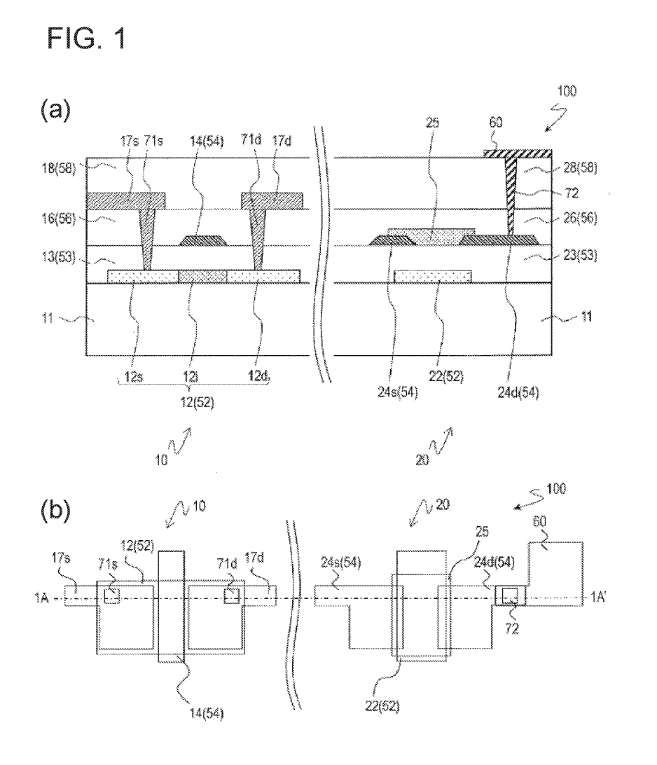

FIGS. 1(a) and 1(b) schematically illustrate a semiconductor device 100 according to an embodiment of the present invention. FIG. 1(a) is a cross-sectional view schematically illustrating the semiconductor device 100 along line 1A-1A′ in FIG. 1(b), and FIG. 1(b) is a plan view schematically illustrating the semiconductor device 100.

As illustrated in FIG. 1(a), the semiconductor device 100 includes a substrate 11, a first TFT 10, and a second TFT 20. The first TFT 10 includes a first semiconductor layer 12 that is supported by the substrate 11, a first gate electrode 14 that is formed on the first semiconductor layer 12 and overlaps with the first semiconductor layer 12 with a first gate insulating layer 13 interposed therebetween, a first insulating layer 16 that covers the first gate electrode 14, and a first source electrode 17s and a first drain electrode 17d that are formed on the first insulating layer 16 and are connected to the first semiconductor layer 12. The second TFT 20 includes a second gate electrode 22 that is supported by the substrate 11, a second semiconductor layer 25 that contains an oxide semiconductor and is formed overlapping with the second gate electrode 22 with a second gate insulating layer 23 interposed therebetween, and a second source electrode 24s and a second drain electrode 24d that are formed between the second gate insulating layer 23 and the second semiconductor layer 25. The first semiconductor layer 12 and the second gate electrode 22 are both formed from the same semiconductor film 52.

The second TFT 20 of the semiconductor device 100 is a bottom-contact TFT in which the bottom surface of the second semiconductor layer 25 contacts the second source electrode 24s and the second drain electrode 24d. When forming the second TFT 20, an etch stop does not need to be formed on the second semiconductor layer 25 that contains an oxide semiconductor. The semiconductor device 100 thus makes it possible to reduce variation in the performance of the second TFT 20 without increasing the number of manufacturing steps (the number of photomasking steps, for example). The semiconductor device 100 also makes it possible to reduce power consumption and/or to achieve a thinner frame without increasing the number of manufacturing steps.

The semiconductor device 100 further includes a pixel electrode 60 that is connected to the second drain electrode 24d via a second contact hole 72, for example. The semiconductor device 100 includes a plurality of pixels arranged in a matrix pattern, for example. Each pixel includes one of the pixel electrodes 60, an opposite electrode that faces the pixel electrode 60, and a liquid crystal layer that is arranged between these electrodes, for example. A voltage is applied to the liquid crystal layer in order to control the orientation of the liquid crystal molecules. A plurality of the second TFTs 20 may be respectively connected to the plurality of pixels and used as pixel switching elements, for example. The second semiconductor layer 25 contains an oxide semiconductor, which results in the second TFT 20 having a low leakage current and makes it possible to reduce power consumption in the semiconductor device 100.

The second gate electrode 22 of the second TFT 20 is connected to a corresponding gate bus line (not illustrated in the figure), for example, and the second source electrode 24s is connected to a corresponding source bus line (not illustrated in the figure), for example. A prescribed signal voltage (such as a scanning signal voltage) is supplied from a gate driver (not illustrated in the figure) to the gate bus line at a prescribed timing, for example. A prescribed signal voltage (such as a display signal voltage) is supplied from a source driver (not illustrated in the figure) to the source bus line at a prescribed timing, for example. The liquid crystal display device is otherwise configured in a well-known manner, and therefore a detailed description will be omitted here.

The first TFT 10 may be used in a driver circuit for supplying signals to the pixels, for example. The driver circuit includes a gate driver or a source driver, for example. The driver circuit is arranged in the periphery around the region in which the pixels of the semiconductor device 100 are arranged (the pixel region), for example. A channel region 12i of the first semiconductor layer 12 of the first TFT 10 is made of low-temperature polysilicon (LTPS), for example. The first TFT 10 thus has high mobility and a low threshold voltage, which makes it possible to reduce power consumption and/or to achieve a thinner frame in the semiconductor device 100.

The semiconductor device 100 may further include a control circuit (not illustrated in the figure) that inputs prescribed signals to the driver circuit (a gate driver or a source driver, for example) that includes the first TFT 10, for example.

The second source electrode 24s may be electrically connected to the source bus line or may be integrated with the source bus line. The second gate electrode 22 is formed from the semiconductor film 52, and therefore electrically connecting the second gate electrode 22 to the gate bus line (which is made of a metal, for example) makes it possible to reduce resistance. The source bus line and the gate bus line may be respectively formed from the same conductive film used to form the second source electrode 24s and the second drain electrode 24d or may be respectively formed from the same conductive film used to form the first source electrode 17s and the first drain electrode 17d, for example.

As illustrated in FIG. 1(a), the first semiconductor layer 12 includes the channel region 12i, a source region 12s, and a drain region 12d. The first gate electrode 14 overlaps with the channel region 12i with the first gate insulating layer 13 interposed therebetween. The semiconductor film 52 used to form the first semiconductor layer 12 and the second gate electrode 22 is made of polysilicon, for example. The source region 12s, the drain region 12d, and the second gate electrode 22 are formed by doping the semiconductor film 52 (which is made of polysilicon, for example) with impurities (such as boron (B)), for example. The first source electrode 17s is electrically connected to the source region 12s via a first contact hole 71s, for example, and the first drain electrode 17d is electrically connected to the drain region 12d via a first contact hole 71d, for example.

As illustrated in FIG. 1(a), the first gate insulating layer 13 and the second gate insulating layer 23 are both formed from the same first insulating film 53, for example. The first gate electrode 14, the second source electrode 24s, and the second drain electrode 24d are all formed from the same first conductive film 54, for example. Forming a plurality of insulating layers or a plurality of electrodes from the same films makes it possible to prevent an increase in the number of steps required to manufacture the semiconductor device. However, the semiconductor device 100 is not limited to the configuration described above. The first gate insulating layer 13 and the second gate insulating layer 23 may be formed from different insulating films than one another. Similarly, the first gate electrode 14, the second source electrode 24s, and the second drain electrode 24d may be formed from different conductive films than one another.

The first TFT 10 further includes a first planarizing layer 18 that covers the first source electrode 17s and the first drain electrode 17d, for example. The second TFT 20 further includes a second insulating layer 26 that covers the second semiconductor layer 25, for example. The second TFT 20 also further includes a second planarizing layer 28 that covers the second insulating layer 26, for example. The first insulating layer 16 and the second insulating layer 26 are both formed from a same second insulating film 56, for example. However, the first insulating layer 16 and the second insulating layer 26 may alternatively be formed from different insulating films than one another. The first planarizing layer 18 and the second planarizing layer 28 are both formed from a same planarizing film 58, for example. Alternatively, the first planarizing layer 18 and the second planarizing layer 28 may be formed from different planarizing films than one another.

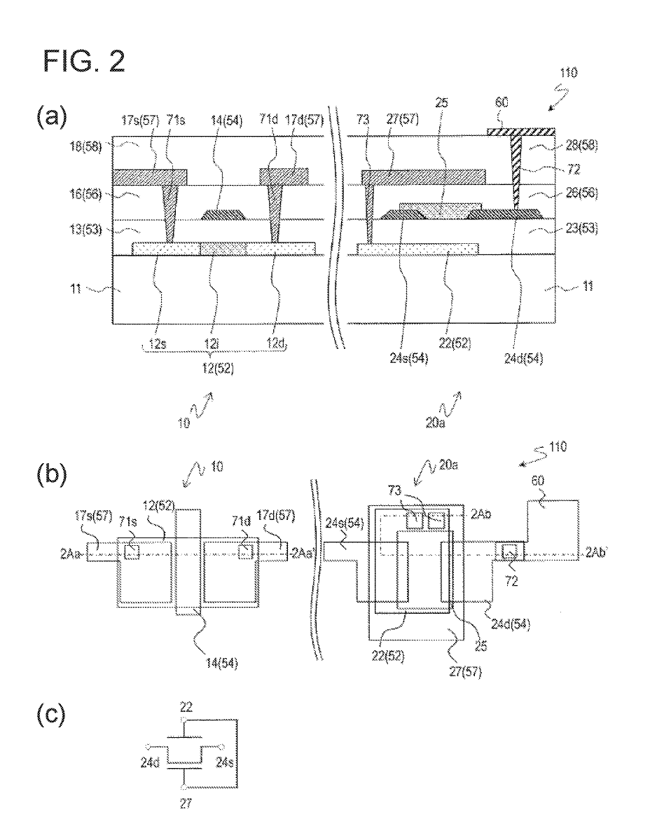

Next, a semiconductor device 110 according to another embodiment of the present invention will be described with reference to FIGS. 2(a) to 2(c). FIGS. 2(a) and 2(b) schematically illustrate the semiconductor device 110. FIG. 2(a) includes cross-sectional views schematically illustrating the semiconductor device 110 along line 2Aa-2Aa′ and line 2Ab-2Ab′ in FIG. 2(b), FIG. 2(b) is a plan view schematically illustrating the semiconductor device 110, and FIG. 2(c) is a circuit diagram of a second TFT 20a of the semiconductor device 110.

As illustrated in FIGS. 2(a) and 2(b), the semiconductor device 110 is different than the semiconductor device 100 in that the semiconductor device 110 further includes a third gate electrode 27 that overlaps with a second semiconductor layer 25 with a second insulating layer 26 interposed therebetween. Other than the third gate electrode 27, the semiconductor device 110 may be the same as the semiconductor device 100.

As illustrated in FIGS. 2(a) and 2(b), the third gate electrode 27 is formed from a same second conductive film 57 as the first source electrode 17s and the first drain electrode 17d, for example.

The second TFT 20a of the semiconductor device 110 is a bottom-contact TFT in which the bottom surface of the second semiconductor layer 25 contacts the second source electrode 24s and the second drain electrode 24d. When forming the second TFT 20a, an etch stop does not need to be formed on the second semiconductor layer 25 that contains an oxide semiconductor. The semiconductor device 110 thus makes it possible to reduce variation in the performance of the second TFT 20a without increasing the number of manufacturing steps (the number of photomasking steps, for example). The semiconductor device 110 also makes it possible to reduce power consumption and/or to achieve a thinner frame without increasing the number of manufacturing steps.

The second TFT 20a of the semiconductor device 110 has a double-gate structure in which the second gate electrode 22 and the third gate electrode 27 are arranged on either side of the second semiconductor layer 25 and in which these two electrodes overlap with the second semiconductor layer 25 with insulating layers (the second gate insulating layer 23 and the second insulating layer 26, respectively, for example) interposed therebetween. TFTs that have a double-gate structure make it possible to distribute the voltage that is applied between the source and drain, thereby making it possible to effectively prevent short-channel effects as well as increases in leakage current. Here, the double-gate structure of the second TFT 20a makes it possible to effectively reduce power consumption in the semiconductor device 110.

The display device disclosed in Patent Document 2 includes bottom-gate, bottom-contact pixel-driving TFTs. In the display device disclosed in Patent Document 2, the gate electrodes of the pixel-driving TFTs are formed from the same conductive film as the gate electrodes of the driver circuit TFTs, and the source electrodes and the drain electrodes of the pixel-driving TFTs are formed from the same conductive film as the source electrodes and the drain electrodes of the driver circuit TFTs. Therefore, giving the pixel-driving TFTs a double-gate structure would require the addition of a new step for forming the top gate electrodes, which would increase the number of manufacturing steps.

In contrast, in the semiconductor device 110, the second gate electrode 22 of the second TFT 20a and the first semiconductor layer 12 of the first TFT 10 are both formed from the same semiconductor film 52. Therefore, the third gate electrode 27 that functions as the top gate electrode in the second TFT 20a can be formed the same second conductive film 57 as the first source electrode 17s and the first drain electrode 17d of the first TFT 10. This makes it possible for the semiconductor device 110 to include the second TFT 20a that has a double-gate structure without increasing the number of manufacturing steps. The double-gate structure of the second TFT 20a makes it possible to effectively prevent increases in leakage current. The semiconductor device 110 also makes it possible to reduce power consumption and/or to achieve a thinner frame without increasing the number of manufacturing steps.

As illustrated in FIGS. 2(a) to 2(c), the second gate electrode 22 is electrically connected to the third gate electrode 27 via a third contact hole 73, for example. The same signal voltage is therefore supplied to both of the gate electrodes, which makes it possible to achieve high mobility in the second TFT 20a. The semiconductor device 110 therefore makes it possible to effectively reduce power consumption.

The second gate electrode 22 and the third gate electrode 27 of the second TFT 20a of the semiconductor device 110 do not necessarily have to be electrically connected. Signal voltages may be separately applied to the second gate electrode 22 and the third gate electrode 27. The signal voltages applied to the second gate electrode 22 and the third gate electrode 27 may be the same or may be different. The third gate electrode 27 may be integrated with the gate bus line or may be electrically connected to the gate bus line. The gate bus line may be formed from the second conductive film 57 or may be formed from the first conductive film 54, for example.

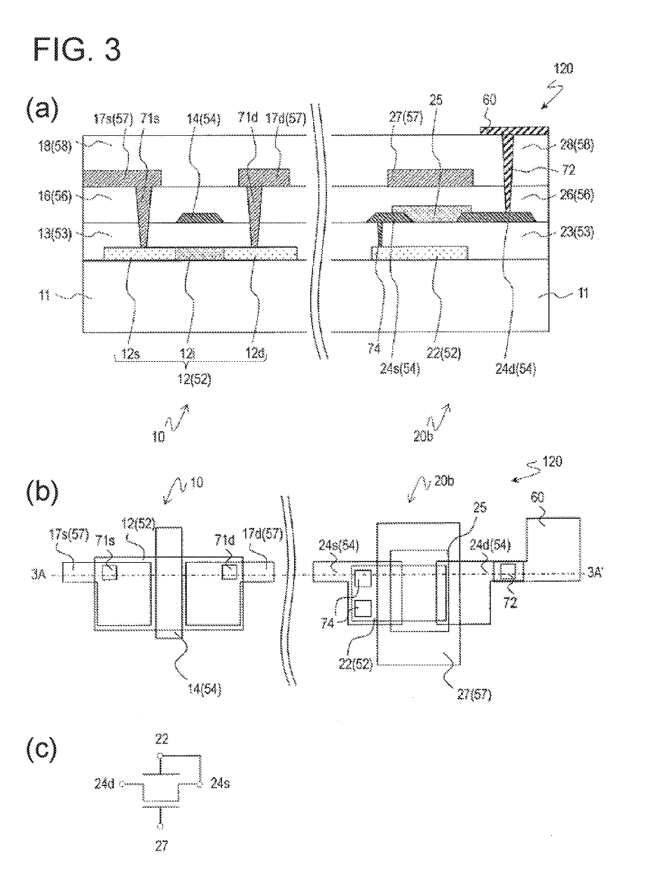

Next, a semiconductor device 120 according to yet another embodiment of the present invention will be described with reference to FIGS. 3(a) to 3(c). FIGS. 3(a) and 3(b) schematically illustrate the semiconductor device 120. FIG. 3(a) is a cross-sectional view schematically illustrating the semiconductor device 120 along line 3A-3A′ in FIG. 3(b), FIG. 3(b) is a plan view schematically illustrating the semiconductor device 120, and FIG. 3(c) is a circuit diagram of a second TFT 20b of the semiconductor device 120.

As illustrated in FIGS. 3(a) to 3(c), the semiconductor device 120 is different than the semiconductor device 110 in that the second gate electrode 22 is electrically connected to the second source electrode 24s. Other than the electrical connections of the second gate electrode 22, the semiconductor device 120 may be the same as the semiconductor device 110. Here, the second gate electrode 22 is electrically connected to the second source electrode 24s via a fourth contact hole 74, for example.

The second TFT 20b of the semiconductor device 120 is a bottom-contact TFT in which the bottom surface of the second semiconductor layer 25 contacts the second source electrode 24s and the second drain electrode 24d. When forming the second TFT 20b, an etch stop does not need to be formed on the second semiconductor layer 25 that contains an oxide semiconductor. The semiconductor device 120 thus makes it possible to reduce variation in the performance of the second TFT 20b without increasing the number of manufacturing steps (the number of photomasking steps, for example). The semiconductor device 120 also makes it possible to reduce power consumption and/or to achieve a thinner frame without increasing the number of manufacturing steps.

In the semiconductor device 120, the second gate electrode 22 of the second TFT 20b and the first semiconductor layer 12 of the first TFT 10 are both formed from the same semiconductor film 52. Therefore, the third gate electrode 27 that functions as the top gate electrode in the second TFT 20b can be formed the same second conductive film 57 as the first source electrode 17s and the first drain electrode 17d of the first TFT 10. This makes it possible for the semiconductor device 120 to include the second TFT 20b that has a double-gate structure without increasing the number of manufacturing steps. The double-gate structure of the second TFT 20b makes it possible to effectively prevent increases in leakage current. The semiconductor device 120 also makes it possible to reduce power consumption and/or to achieve a thinner frame without increasing the number of manufacturing steps.

In the semiconductor device 120, the second gate electrode 22 is electrically connected to the second source electrode 24s, thereby making it possible to reduce threshold voltage shift in the second TFT 20b. This makes it possible to prevent negative shifts in the threshold voltage, for example, thereby making it possible to prevent increases in leakage current in the second TFT 20b. Moreover, this also makes it possible to prevent positive shifts in the threshold voltage, thereby making it possible to prevent increases in the power consumed by operation of the second TFT 20b. The semiconductor device 120 also makes it possible to reduce power consumption and/or to achieve a thinner frame without increasing the number of manufacturing steps.

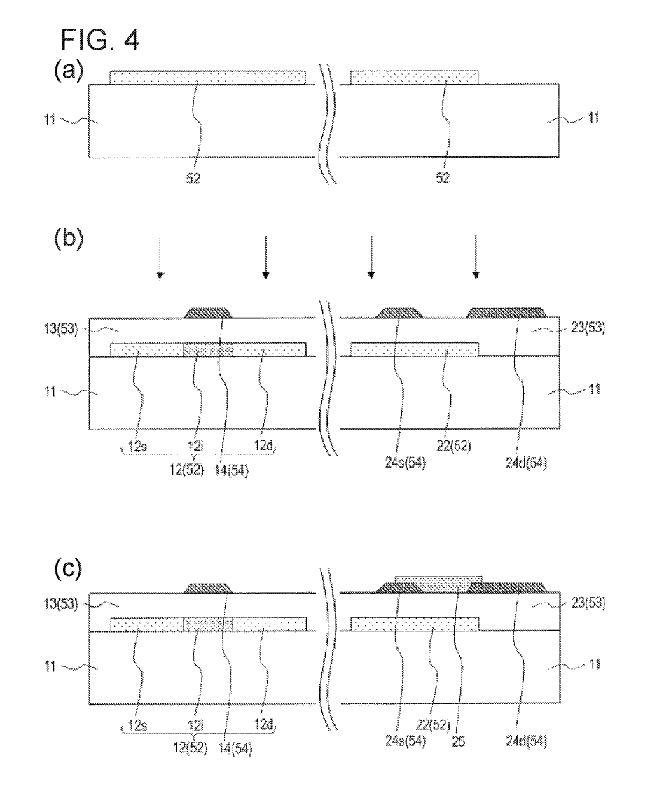

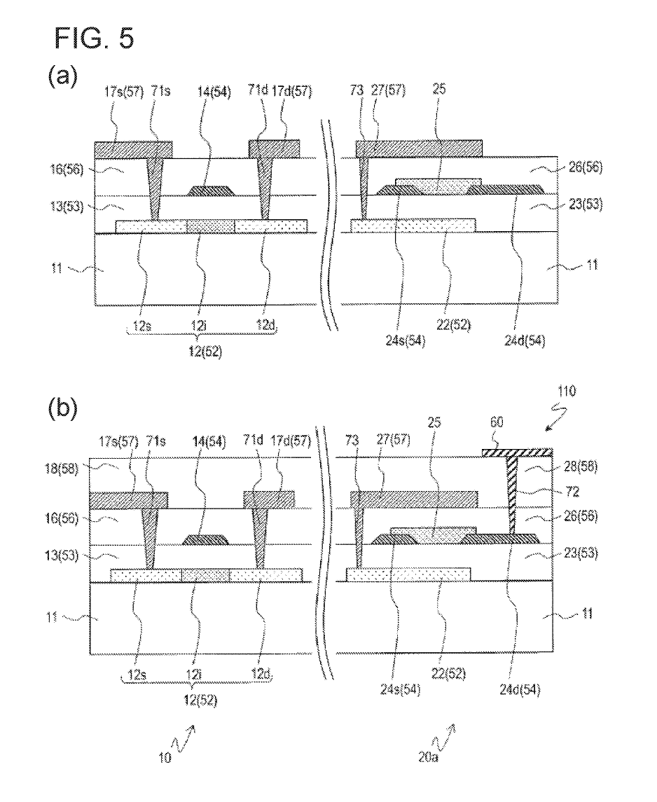

Next, a method of manufacturing the semiconductor device 110 will be described with reference to FIGS. 4(a) to 4(c) and FIGS. 5(a) to 5(b). FIGS. 4(a) to 4(c) and FIGS. 5(a) and 5(b) are cross-sectional views schematically illustrating steps in an example of the method of manufacturing the semiconductor device 110.

First, as illustrated in FIG. 4(a), a semiconductor film 52 is formed on a substrate 11.

For example, the semiconductor film 52 is formed by depositing a semiconductor material over the entire surface of the substrate 11 and then patterning the semiconductor film 52 into a prescribed shape or pattern (such as an island shape). Here, the semiconductor film 52 is patterned to form regions for a first TFT 10 and a second TFT 20a (these will be referred to as “the semiconductor film 52 for the first TFT region” and “the semiconductor film 52 for the second TFT region,” respectively).

The substrate 11 is an insulating substrate such as a glass substrate, for example. The semiconductor film 52 is made of polysilicon, for example. The polysilicon semiconductor film 52 is formed by using a CVD method to deposit amorphous silicon (a-Si) onto the substrate 11 and then using an excimer laser to melt and crystallize the resulting thin film (excimer laser annealing), for example. The thickness of the semiconductor film 52 is 30 nm to 100 nm, for example.

Next, as illustrated in FIG. 4(b), a first gate insulating layer 13 and a second gate insulating layer 23 are formed.

The first gate insulating layer 13 and the second gate insulating layer 23 are formed from a first insulating film 53 formed by depositing an insulating material over the entire surface of the substrate 11, for example. A CVD method or a PVD method may be used to deposit the insulating material, for example. After depositing the first insulating film 53, impurities may be implanted into the entire surface of the substrate 11 as necessary. Moreover, after depositing the first insulating film 53, the first insulating film 53 may be patterned into a prescribed shape (or pattern). The first gate insulating layer 13 and the second gate insulating layer 23 each contain silicon dioxide (SiO₂), silicon nitride (SiNₓ), silicon oxynitride (SiOₓN_{y}, x>y), or silicon nitride oxide (SiNₓO_{y}, x>y), for example. The first gate insulating layer 13 and the second gate insulating layer 23 may be single layers or may have a multilayer structure that includes a plurality of films. The first gate insulating layer 13 and the second gate insulating layer 23 are each 50 nm to 300 nm in thickness, for example.

Next, a first gate electrode 14, a second source electrode 24s, and a second drain electrode 24d are formed. These electrodes are formed by depositing a conductive material (such as a metal) onto the first insulating film 53 to form a first conductive film 54 and then patterning that first conductive film 54 into a prescribed shape (or pattern) using a photolithography process, for example. The first gate electrode 14 overlaps with a portion of the semiconductor film 52 for the first TFT region with the first gate insulating layer 13 interposed therebetween. The second source electrode 24s and the second drain electrode 24d may overlap with a portion of the semiconductor film 52 for the second TFT region with the second gate insulating layer 23 interposed therebetween.

The first conductive film 54 is made of a metal such as aluminum (Al), tungsten (W), molybdenum (Mo), tantalum (Ta), chromium (Cr), titanium (Ti), or copper (Cu), for example. The first conductive film 54 may also be an alloy that contains the abovementioned metals or may contain a nitride of the abovementioned metals. Here, the first gate electrode 14, the second source electrode 24s, and the second drain electrode 24d are formed by depositing titanium to form the first conductive film 54, for example. The first gate electrode 14, the second source electrode 24s, and the second drain electrode 24d are each 70 nm to 300 nm in thickness, for example.

Next, impurities (such as boron) are implanted into the semiconductor film 52 in order to form a first semiconductor layer 12 and a second gate electrode 22. These impurities may be implanted using an ion implantation process or a thermal diffusion process, for example. After the impurities are implanted, an annealing process is performed as necessary.

When implanting the impurities into the semiconductor film 52, the first gate electrode 14, the second source electrode 24s, and the second drain electrode 24d that are formed from the first conductive film 54 function as a mask. When the impurities are implanted, the portions of the semiconductor film 52 for the first TFT region that do not overlap with the first gate electrode 14 become conductive, thereby forming a source region 12s and a drain region 12d. No impurities are implanted into the portion that does overlap with the first gate electrode 14, which therefore becomes a channel region 12i. In this way, the first semiconductor layer 12 that includes the channel region 12i, the source region 12s, and the drain region 12d is formed from the semiconductor film 52 for the first TFT region.

When the impurities are implanted into the portion of the semiconductor film 52 for the second TFT region that does not overlap with the second source electrode 24s or the second drain electrode 24d, this portion becomes conductive, thereby forming the second gate electrode 22.

Next, as illustrated in FIG. 4(c), a second semiconductor layer 25 is formed on the second source electrode 24s and the second drain electrode 24d.

The second semiconductor layer 25 contains an oxide semiconductor. The second semiconductor layer 25 contains an indium gallium zinc oxide semiconductor (hereinafter, simply an “In—Ga—Zn—O semiconductor”), for example. Here, the In—Ga—Zn—O semiconductor is a ternary oxide of indium (In), gallium (Ga), and zinc (Zn). The composition ratio of the In, Ga, and Zn is not particularly limited, and the oxide semiconductor may contain these elements in ratios such as In:Ga:Zn=2:2:1, In:Ga:Zn=1:1:1, and In:Ga:Zn=1:1:2, for example. Here, the second semiconductor layer 25 may contain InGaO₃(ZnO)₅, for example.

TFTs that have an In—Ga—Zn—O semiconductor layer exhibit high mobility (more than 20 times that of amorphous silicon (a-Si) TFTs) as well as low leakage current (less than 1/100th that of a-Si TFTs) and are therefore suitable for use both as driver TFTs and pixel TFTs. Moreover, the high mobility of TFTs that have an In—Ga—Zn—O semiconductor layer facilitates miniaturization of the TFT. Therefore, using TFTs that have an In—Ga—Zn—O semiconductor layer makes it possible to significantly reduce power consumption in a semiconductor device and/or improve resolution in a semiconductor device.

The In—Ga—Zn—O semiconductor may be amorphous (non-crystalline) or may contain crystalline portions. When using a crystalline In—Ga—Zn—O semiconductor, it is preferable that a crystalline In—Ga—Zn—O semiconductor in which the c-axis is approximately orthogonal to the layering plane be used. Japanese Patent Application Laid-Open Publication No. 2012-134475, for example, discloses an example of the crystal structure of such an In—Ga—Zn—O semiconductor. The entire contents of Japanese Patent Application Laid-Open Publication No. 2012-134475 are hereby incorporated by reference in the present specification.

The second semiconductor layer 25 may contain a different oxide semiconductor instead of the In—Ga—Zn—O semiconductor. For example, the second semiconductor layer 25 may contain a Zn—O semiconductor (ZnO), an In—Zn—O semiconductor (IZO (registered trademark)), a Zn—Ti—O semiconductor (ZTO), a Cd—Ge—O semiconductor, a Cd—Pb—O semiconductor, cadmium oxide (CdO), an Mg—Zn—O semiconductor, an In—Sn—Zn—O semiconductor (such as In₂O₃—SnO₂—ZnO), an In—Ga—Sn—O semiconductor, or the like.

Here, “a Zn—O semiconductor” includes both semiconductors in which no impurity elements are added to ZnO and semiconductors in which impurities are added to ZnO. Moreover, “a Zn—O semiconductor” also includes semiconductors to which one or more impurity elements belonging to Group 1 elements, Group 13 elements, Group 14 elements, Group 15 elements, Group 17 elements, or the like have been added, for example. In addition, “a Zn—O semiconductor” also includes magnesium zinc oxide (MgₓZn₁₋ₓO) and cadmium zinc oxide (CdₓZn₁₋ₓO), for example. The Zn—O semiconductor may be amorphous (non-crystalline), polycrystalline, or be in a crystallite state that contains a mixture of the non-crystalline and polycrystalline phases.

The thickness of the second semiconductor layer 25 is 30 nm to 100 nm, for example. Here, an oxide semiconductor film is formed using a sputtering process and then patterned into a prescribed shape (or pattern) using a photolithography process in order to form the second semiconductor layer 25, for example. After forming the second semiconductor layer 25, an annealing process may be performed as necessary. Here, the annealing process may be performed in air, in a nitrogen atmosphere, or in an oxygen atmosphere, for example. Moreover, after the thin film of the oxide semiconductor has been formed, the annealing process may be performed before or after patterning.

Next, as illustrated in FIG. 5(a), a first insulating layer 16 and a second insulating layer 26 are formed.

The first insulating layer 16 and the second insulating layer 26 are formed from a second insulating film 56 formed by depositing an insulating material over the entire surface of the substrate 11, for example. Moreover, after depositing the second insulating film 56, the second insulating film 56 may be patterned into a prescribed shape (or pattern). The first insulating layer 16 and the second insulating layer 26 each contain silicon dioxide (SiO₂), silicon nitride (SiNₓ), silicon oxynitride (SiOₓN_{y}, x>y), or silicon nitride oxide (SiNₓO_{y}, x>y), for example. The first insulating layer 16 and the second insulating layer 26 may be single layers or may have a multilayer structure that includes a plurality of films. The first insulating layer 16 and the second insulating layer 26 are each 50 nm to 300 nm in thickness, for example. The first insulating film 53 and the second insulating film 56 may have the same thickness or may have different thicknesses than one another. When the second TFT 20a has a double-gate structure, it is preferable that the second gate insulating layer 23 and the second insulating layer 26 have the same thickness.

Next, two first contact holes 71s and 71d and a third contact hole 73 are formed. The first contact holes 71s and 71d are formed as openings in the first gate insulating layer 13 and the first insulating layer 16 and reach down to the source region 12s and the drain region 12d, respectively. The third contact hole 73 is formed as an opening in the second gate insulating layer 23 and the second insulating layer 26 and reaches down to the second gate electrode 22. The contact holes are formed using a photolithography process that includes a step for forming, on the insulating layers, a resist mask that has openings for forming the contact holes as well as a step for etching the insulating layers, for example.

Next, a first source electrode 17s, a first drain electrode 17d, and a third gate electrode 27 are formed. These electrodes are formed by depositing a conductive material (such as a metal) onto the second insulating film 56 to form a second conductive film 57 and then patterning that second conductive film 57 into a prescribed shape (or pattern) using a photolithography process, for example. The first source electrode 17s and the first drain electrode 17d are respectively electrically connected to the source region 12s and the drain region 12d via the first contact hole 71s and the first contact hole 71d, respectively.

The second conductive film 57 is made of a metal such as aluminum (Al), tungsten (W), molybdenum (Mo), tantalum (Ta), chromium (Cr), titanium (Ti), or copper (Cu), for example. The second conductive film 57 may also be an alloy that contains the abovementioned metals or may contain a nitride of the abovementioned metals. Here, the first source electrode 17s, the first drain electrode 17d, and the third gate electrode 27 are formed by depositing titanium to form the second conductive film 57 and then patterning the second conductive film 57, for example. The first source electrode 17s, the first drain electrode 17d, and the third gate electrode 27 are each 100 nm to 600 nm in thickness, for example.

Next, as illustrated in FIG. 5(b), a first planarizing layer 18 and a second planarizing layer 28 are formed. The first planarizing layer 18 and the second planarizing layer 28 are formed from a planarizing film 58 formed by depositing an insulating material over the entire surface of the substrate 11, for example. The planarizing film 58 contains an inorganic insulating material (such as silicon dioxide, silicon nitride, silicon oxynitride, or silicon nitride oxide) or an organic insulating material, for example.

Next, a second contact hole 72 is formed. The second contact hole 72 is formed as an opening in the second planarizing layer 28 and the second insulating layer 26 and reaches down to the second drain electrode 24d.

Next, a pixel electrode 60 is formed. The pixel electrode 60 is made of a conductive material (such as an oxide semiconductor) that is transparent to visible light, for example. The pixel electrode 60 is electrically connected to the second drain electrode 24d via the second contact hole 72.

This completes the method of manufacturing the semiconductor device 110 as per the steps described above.

A method of manufacturing the semiconductor device 100 may be the same as the method of manufacturing the semiconductor device 110 except for the step of forming the third gate electrode 27. Moreover, a method of manufacturing the semiconductor device 120 may be the same as the method of manufacturing the semiconductor device 110 except for the electrical connections formed for the second gate electrode 22.

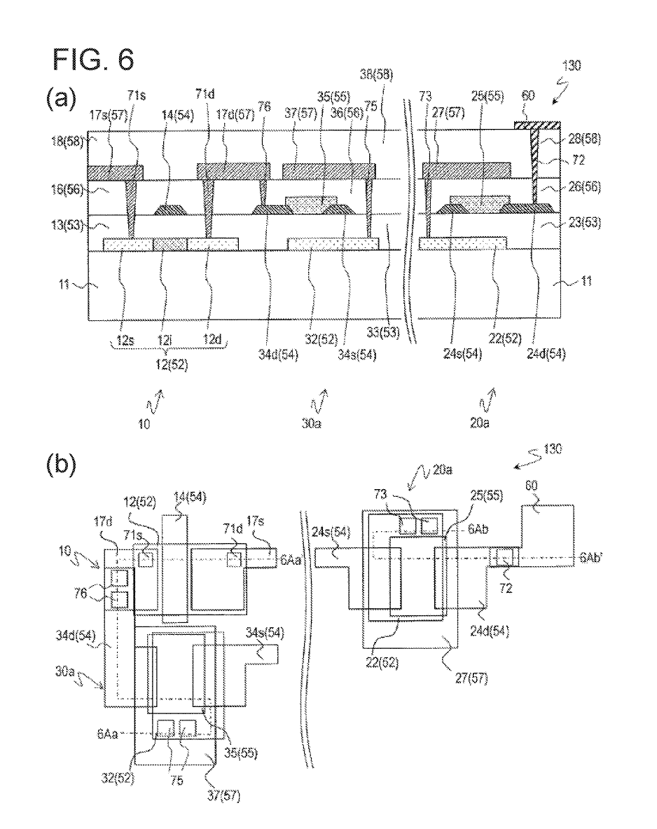

Next, a semiconductor device 130 according to yet another embodiment of the present invention will be described with reference to FIGS. 6(a) and 6(b). FIGS. 6(a) and 6(b) schematically illustrate the semiconductor device 130. FIG. 6(a) includes cross-sectional views schematically illustrating the semiconductor device 130 along line 6Aa-6Aa′ and line 6Ab-6Ab′ in FIG. 6(b), and FIG. 6(b) is a plan view schematically illustrating the semiconductor device 130.

As illustrated in FIGS. 6(a) and 6(b), the semiconductor device 130 is different than the semiconductor device 110 in that the semiconductor device 130 further includes a third TFT 30a. Other than the additional inclusion of the third TFT 30a, the semiconductor device 130 may be the same as the semiconductor device 110.

The third TFT 30a includes a fourth gate electrode 32 that is supported by the substrate 11, a third semiconductor layer 35 that contains an oxide semiconductor and is formed overlapping with the fourth gate electrode 32 with a third gate insulating layer 33 interposed therebetween, and a third source electrode 34s and a third drain electrode 34d that are formed between the third gate insulating layer 33 and the third semiconductor layer 35. The third drain electrode 34d is electrically connected to the first drain electrode 17d of the first TFT 10. Here, the third drain electrode 34d is electrically connected to the first drain electrode 17d via a sixth contact hole 76, for example.

The first TFT 10 and the third TFT 30a form a CMOS inverter circuit. In the semiconductor device 130, the first TFT 10 is a p-channel TFT and the third TFT 30a is an n-channel TFT, for example. The first TFT 10 and the third TFT 30a that form the CMOS inverter circuit can be used in a driver circuit for the semiconductor device 130, thereby making it possible to reduce power consumption in the driver circuit. Moreover, reducing power consumption in the driver circuit makes it possible to reduce the area of the region in which the driver circuit is formed. This makes it possible to reduce power consumption and/or to achieve a thinner frame in the semiconductor device 130.

The second TFT 20a of the semiconductor device 130 is a bottom-contact TFT in which the bottom surface of the second semiconductor layer 25 contacts the second source electrode 24s and the second drain electrode 24d. When forming the second TFT 20a, an etch stop does not need to be formed on the second semiconductor layer 25 that contains an oxide semiconductor. The semiconductor device 130 thus makes it possible to reduce variation in the performance of the second TFT 20a without increasing the number of manufacturing steps (the number of photomasking steps, for example). The semiconductor device 130 also makes it possible to reduce power consumption and/or to achieve a thinner frame without increasing the number of manufacturing steps.

As illustrated in FIGS. 6(a) and 6(b), the third TFT 30a further includes a fifth gate electrode 37 that overlaps with the third semiconductor layer 35 with a third insulating layer 36 interposed therebetween, for example. The third TFT 30a has a double-gate structure in which the fourth gate electrode 32 and the fifth gate electrode 37 are arranged on either side of the third semiconductor layer 35. The third TFT 30a has the same structure as the second TFT 20a, for example. The layers and films of the third TFT 30a can therefore be formed from the same materials and in the same steps as the corresponding layers and films of the second TFT 20a, for example. As a result, no additional manufacturing steps are required to form the third TFT 30a in the semiconductor device 130. The double-gate structure of the third TFT 30a makes it possible to effectively reduce power consumption in the semiconductor device 130. The semiconductor device 130 also makes it possible to effectively reduce power consumption and/or achieve a thinner frame without increasing the number of manufacturing steps. As illustrated in FIGS. 6(a) and 6(b), the fourth gate electrode 32 is electrically connected to the fifth gate electrode 37 via a fifth contact hole 75, for example.

As illustrated in FIGS. 6(a) and 6(b), the fourth gate electrode 32 is formed from the second conductive film 52, for example. The third gate insulating layer 33 is formed from the first insulating film 53, for example. The third semiconductor layer 35 that contains an oxide semiconductor is formed from a same oxide semiconductor film 55 as the second semiconductor layer 25, for example. The third source electrode 34s and the third drain electrode 34d are formed from the first conductive film 54, for example. The third insulating layer 36 is formed from the second insulating film 56, for example. The fifth gate electrode 37 is formed from the second conductive film 57, for example. The third TFT 30a also further includes a third planarizing layer 38 that covers the third insulating layer 36, for example. The third planarizing layer 38 is formed from the planarizing film 58, for example.

The second TFT 20a of the semiconductor device 130 does not necessarily need to include the third gate electrode 27. The second TFT of the semiconductor device 130 may be the same as the second TFT 20 of the semiconductor device 100. The second TFT of the semiconductor device 130 may also be the same as the second TFT 20b of the semiconductor device 120.

The third TFT 30a of the semiconductor device 130 does not necessarily need to include the fifth gate electrode 37. The third TFT of the semiconductor device 130 may have the same structure as the second TFT 20 of the semiconductor device 100 (which is a bottom-gate, bottom-contact TFT).

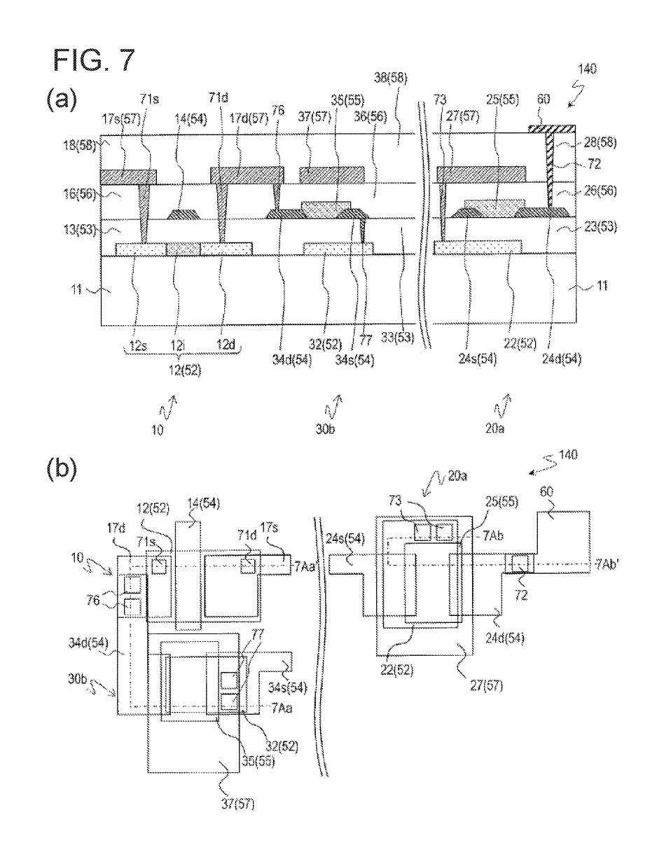

Next, a semiconductor device 140 according to yet another embodiment of the present invention will be described with reference to FIGS. 7(a) and 7(b). FIGS. 7(a) and 7(b) schematically illustrate the semiconductor device 140. FIG. 7(a) includes cross-sectional views schematically illustrating the semiconductor device 140 along line 7Aa-7Aa′ and line 7Ab-7Ab′ in FIG. 7(b), and FIG. 7(b) is a plan view schematically illustrating the semiconductor device 140.

As illustrated in FIGS. 7(a) and 7(b), the semiconductor device 140 is different than the semiconductor device 130 in that the fourth gate electrode 32 is electrically connected to the third source electrode 34s. Other than the electrical connections of the fourth gate electrode 32, the semiconductor device 140 may be the same as the semiconductor device 130. Here, the fourth gate electrode 32 is electrically connected to the third source electrode 34s via a seventh contact hole 77, for example.

The second TFT 20a of the semiconductor device 140 is a bottom-contact TFT in which the bottom surface of the second semiconductor layer 25 contacts the second source electrode 24s and the second drain electrode 24d. When forming the second TFT 20a, an etch stop does not need to be formed on the second semiconductor layer 25 that contains an oxide semiconductor. The semiconductor device 140 thus makes it possible to reduce variation in the performance of the second TFT 20a without increasing the number of manufacturing steps (the number of photomasking steps, for example). The semiconductor device 140 also makes it possible to reduce power consumption and/or to achieve a thinner frame without increasing the number of manufacturing steps.

A third TFT 30b of the semiconductor device 140 further includes the fifth gate electrode 37 that overlaps with the third semiconductor layer 35 with the third insulating layer 36 interposed therebetween, for example. The third TFT 30b has a double-gate structure in which the fourth gate electrode 32 and the fifth gate electrode 37 are arranged on either side of the third semiconductor layer 35. The third TFT 30b has the same structure as the second TFT 20b of the semiconductor device 120, for example.

The layers and films of the third TFT 30b can therefore be formed from the same materials and in the same steps as the corresponding layers and films of the second TFT 20a, for example. As a result, no additional manufacturing steps are required to form the third TFT 30b in the semiconductor device 140. The double-gate structure of the third TFT 30b makes it possible to effectively reduce power consumption in the semiconductor device 140. The semiconductor device 140 also makes it possible to effectively reduce power consumption and/or achieve a thinner frame without increasing the number of manufacturing steps.

In the embodiments described above, the source electrodes and drain electrodes of the TFTs (the first TFT, the second TFT, and the third TFT) were formed from the same conductive film (or semiconductor film), and the gate electrodes were formed from a conductive film different than the former conductive film. However, the embodiments of the present invention are not limited to this example. The source electrode and/or drain electrode and the gate electrode may all be formed from the same conductive film. In this case, it is preferable that the source electrodes, the drain electrodes, and the gate electrodes of the TFTs (the first TFT, the second TFT, and the third TFT) be formed from one of the semiconductor film 52, the first conductive film 54, and the second conductive film 57 in order to prevent an increase in the number of manufacturing steps.

### INDUSTRIAL APPLICABILITY

The semiconductor devices according to the embodiments of the present invention are suitable for use in a wide variety of monolithic driver-type display devices, including liquid crystal display devices, organic EL display devices, and electrophoretic display devices, for example.

### DESCRIPTION OF REFERENCE CHARACTERS

10 first TFT
11 substrate
12 first semiconductor layer
13 first gate insulating layer
14 first gate electrode
16 first insulating layer
17s first source electrode
17d first drain electrode
18 first planarizing layer
20, 20a, 20b second TFT
22 second gate electrode
23 second gate insulating layer
24s second source electrode
24d second drain electrode
25 second semiconductor layer
26 second insulating layer
27 third gate electrode
28 second planarizing layer
30a, 30b third TFT
32 fourth gate electrode
33 third gate insulating layer
34s third source electrode
34d third drain electrode
35 third semiconductor layer
36 third insulating layer
37 fifth gate electrode
38 third planarizing layer
52 semiconductor film
53 first insulating film
54 first conductive film
55 oxide semiconductor film
56 second insulating film
57 second conductive film
58 planarizing film
60 pixel electrode
71s, 71d first contact hole
72 second contact hole
73 third contact hole
74 fourth contact hole
75 fifth contact hole
76 sixth contact hole
77 seventh contact hole
100, 110, 120, 130, 140 semiconductor device

1. A semiconductor device, comprising:
a substrate;
a first thin film transistor including a first semiconductor layer supported by the substrate, a first gate electrode formed on the first semiconductor layer so as to overlap the first semiconductor layer with a gate insulating layer therebetween, a first insulating layer covering the first gate electrode, and a first source electrode and a first drain electrode formed on the first insulating layer and connected to the first semiconductor layer; and
a second thin film transistor including a second gate electrode supported by the substrate, a second semiconductor layer containing an oxide semiconductor and formed so as to overlap the second gate electrode with a second gate insulating layer therebetween, and a second source electrode and a second drain electrode formed between the second gate insulating layer and the second semiconductor layer,
wherein the first semiconductor layer and the second gate electrode are formed from a same semiconductor film.

2. The semiconductor device according to claim 1, wherein the first gate insulating layer and the second gate insulating layer are formed from a same first insulating film.

3. The semiconductor device according to claim 1, wherein the first gate electrode, the second source electrode, and the second drain electrode are formed from a same first conductive film.

4. The semiconductor device according to claim 1, further comprising:
a second insulating layer covering the second semiconductor layer,
wherein the first insulating layer and the second insulating layer are formed from a same second insulating film.

5. The semiconductor device according to claim 4, further comprising:
a third gate electrode overlapping the second semiconductor layer with the second insulating layer interposed therebetween.

6. The semiconductor device according to claim 5, wherein the first source electrode, the first drain electrode, and the third gate electrode are formed from a same second conductive film.

7. The semiconductor device according to claim 5, wherein the second gate electrode is electrically connected to the third gate electrode.

8. The semiconductor device according to claim 5, wherein the second gate electrode is electrically connected to the second source electrode.

9. The semiconductor device according to claim 1, wherein the oxide semiconductor of the second semiconductor layer is contains an In—Ga—Zn—O semiconductor.

10. The semiconductor device according to claim 9, wherein the In—Ga—Zn—O semiconductor contains a crystalline portion.

11. The semiconductor device according to claim 1, further comprising:
a third thin film transistor including a fourth gate electrode supported by the substrate, a third semiconductor layer containing an oxide semiconductor and formed so as to overlap the fourth gate electrode with a third gate insulating layer therebetween, and a third source electrode and a third drain electrode formed between the third gate insulating layer and the third semiconductor layer,
wherein the third drain electrode is electrically connected to the first drain electrode.

12. The semiconductor device according to claim 11, wherein the oxide semiconductor of the third semiconductor layer is an In—Ga—Zn—O semiconductor.

13. The semiconductor device according to claim 12, wherein the In—Ga—Zn—O semiconductor of the third semiconductor layer contains a crystalline portion.
